(19) United States
(12) Patent Application Publication
(10) Pub. No.: US 2026/0277118 A1
(43) Pub. Date: Sep. 17, 2026

(54) OVERLAY METROLOGY BASED ON A FRINGE PATTERN

(71) Applicant: ASML NETHERLANDS B.V., Veldhoven (NL)

(72) Inventors: Simon Reinald HUISMAN, Eindhoven (NL); Sebastianus Adrianus GOORDEN, Eindhoven (NL); Filippo ALPEGGIANI, Waalre (NL)

(73) Assignee: ASML NETHERLANDS B.V., Veldhoven (NL)

(21) Appl. No.: 19/167,167

(22) PCT Filed: Mar. 13, 2024
(86) PCT No.: PCT/EP2024/056740

§ 371 Date: Sep. 19, 2025

Related U.S. Application Data
(60) Provisional application No. 63/457,680, filed on Apr. 6, 2023.
(60) Provisional application No. 63/625,743, filed on Jan. 26, 2024.

(51) Int. Cl. G03F 7/00; G01B 11/27

(52) U.S. Cl. CPC G03F 7/706837; G01B 11/272; G03F 7/70633; G03F 7/70683; G03F 7/706851

(57) ABSTRACT

Measuring overlay using a microscope-based sensor, which provides the ability to measure alignment and overlay with a single system, or other or additional advantages. The signal from the sensor is an intensity modulated fringe pattern (e.g., an interference pattern). The sensor is configured to generate the intensity modulated fringe pattern based on diffracted radiation received from a first metrology mark in a first layer of a patterned substrate and a second metrology mark in a second layer of the patterned substrate. The intensity modulated fringe pattern is filtered for an expected fringe period. An amplitude, phase, and/or other parameter of fringes of the filtered fringe pattern are used to determine an overlay value.

### CROSS-REFERENCE TO RELATED APPLICATIONS

This application claims priority of a U.S. application Ser. No. 63/457,680 which was filed on 6 Apr. 2023 and U.S. application 63/625,743, which was filed on 26 Jan. 2024, both of which are incorporated herein in their entireties by reference.

### TECHNICAL FIELD

This description relates generally to overlay metrology based on a fringe pattern.

### BACKGROUND

A lithographic projection apparatus can be used, for example, in the manufacture of integrated circuits (ICs). A patterning device (e.g., a mask) may include or provide a pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate includes a plurality of adjacent target portions to which the pattern is transferred successively by the lithographic projection apparatus, one target portion at a time. In one type of lithographic projection apparatus, the pattern on the entire patterning device is transferred onto one target portion in one operation. Such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the pattern on the patterning device are transferred to one target portion progressively.

Prior to transferring the pattern from the patterning device to the substrate, the substrate may undergo various procedures, such as priming, resist coating, and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, deposition, chemo-mechanical polishing, etc., all intended to finish the individual layer of the device. If several layers are required in the device, then the whole procedure, or a variant thereof, is repeated for each layer. Eventually, a device will be present in each target portion on the substrate. These devices are then separated from one another by a technique such as dicing or sawing, such that the individual devices can be mounted on a carrier, connected to pins, etc.

Thus, manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, deposition, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, deposition, etc.

Lithography is a central step in the manufacturing of device such as ICs, where patterns formed on substrates define functional elements of the devices, such as microprocessors, memory chips, etc. Similar lithographic techniques are also used in the formation of flat panel displays, micro-electro mechanical systems (MEMS) and other devices.

As semiconductor manufacturing processes continue to advance, the dimensions of functional elements have continually been reduced while the number of functional elements, such as transistors, per device has been steadily increasing over decades, following a trend commonly referred to as “Moore's law”. At the current state of technology, layers of devices are manufactured using lithographic projection apparatuses that project a design layout onto a substrate using illumination from a deep-ultraviolet or extreme ultraviolet illumination source, creating individual functional elements having dimensions well below 100 nm, i.e., less than half the wavelength of the radiation from the illumination source (e.g., a 193 nm illumination source).

This process in which features with dimensions smaller than the classical resolution limit of a lithographic projection apparatus are printed, is commonly known as low-k₁ lithography, according to the resolution formula CD=k₁×λ/NA, where λ is the wavelength of radiation employed, NA is the numerical aperture of projection optics in the lithographic projection apparatus, CD is the “critical dimension”—generally the smallest feature size printed-and k₁ is an empirical resolution factor. In general, the smaller k₁ the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the patterning device. These include, for example, but are not limited to, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET).

### SUMMARY

Measuring overlay using a microscope based sensor is described. This provides the ability to measure overlay with a single system, among other advantages. The signal from the sensor is an intensity modulated fringe pattern (e.g., an interference pattern). The sensor is configured to generate the intensity modulated fringe pattern based on diffracted radiation received from a first metrology mark in a first layer of a patterned substrate and a second metrology mark in a second layer of the patterned substrate. The intensity modulated fringe pattern is filtered for an expected fringe period. An amplitude, phase, and/or other parameters of fringes of the filtered fringe pattern are used to determine an overlay value.

According to an embodiment, an overlay metrology system is provided. The overlay metrology system comprises a radiation sensor configured to generate a metrology signal based on diffracted radiation received from a first metrology mark in a first layer of a patterned substrate and a second metrology mark in a second layer of the patterned substrate. The metrology signal comprises an intensity modulated fringe pattern for the diffracted radiation. The overlay metrology system comprises one or more processors operatively coupled to the radiation sensor. The one or more processors are configured to filter the intensity modulated fringe pattern for an expected fringe period; determine one or more parameters of fringes in the intensity modulated fringe pattern based on a filtered intensity modulated fringe pattern; and determine an overlay value based on the one or more parameters.

In some embodiments, the second metrology mark is above the first metrology mark.

In some embodiments, the radiation sensor is configured such that the intensity modulated fringe pattern for the diffracted radiation comprises an interference pattern generated based on diffracted radiation from the first metrology mark and the second metrology mark.

In some embodiments, the first metrology mark in the first layer is shifted relative to the second metrology mark by a known bias amount.

In some embodiments, the overlay metrology system comprises a radiation source operatively coupled to the one or more processors and the radiation sensor. The radiation source is configured to irradiate the first and second metrology marks with radiation.

In some embodiments, radiation from the radiation source is on axis. In some embodiments, radiation from the radiation source is off axis. In some embodiments, radiation from the radiation source is spatially incoherent. In some embodiments, radiation from the radiation source is spatially coherent.

In some embodiments, the first and second metrology marks comprise a diffraction-based overlay metrology mark. In some embodiments, the first and second metrology marks comprise gratings. In some embodiments, the gratings have the same pitch. In some embodiments, the expected fringe period is determined based on the pitch. In some embodiments, the first and second metrology marks form a Micro Diffraction Based Overlay (μDBO) target, with the first and second metrology marks comprising gratings in the first and second layers of the patterned substrate.

In some embodiments, the intensity modulated fringe pattern comprises a one or more dimensional interference pattern.

In some embodiments, the radiation sensor comprises a camera.

In some embodiments, the one or more processors are configured such that determining the one or more parameters of the fringes comprises determining a first amplitude and a second amplitude of fringes in the filtered intensity modulated fringe pattern; and determining the overlay value is based on a difference between the amplitudes, a summation of the amplitudes, and a calibration factor.

In some embodiments, the calibration factor is determined based on radiation wavelength, a layer spacing between the first metrology mark and the second metrology mark, a ratio of diffraction efficiencies associated with the first metrology mark in the first layer of the patterned substrate and the second metrology mark in the second layer, grating pitch, and grating depth. In some embodiments, the calibration factor is determined by training a model associated with the overlay metrology system.

In some embodiments, the first amplitude is associated with a positive bias and the second amplitude is associated with a negative bias of the first and second metrology marks relative to each other. In some embodiments, the first amplitude is associated with a segment of a metrology mark with a positive bias and the second amplitude is associated with a segment of a metrology mark with a negative bias of the first and second metrology marks relative to each other. In some embodiments, the first amplitude is associated with a positive bias and the second amplitude is associated with a negative bias of the entire first and second metrology marks relative to each other.

In some embodiments, overlay value determinations are insensitive to surrounding structures in the first and second layers of the patterned substrate.

In some embodiments, the one or more processors are configured such that determining the one or more parameters of the fringes comprises determining an amplitude and an average intensity of fringes in the filtered intensity modulated fringe pattern; and determining the overlay value is based on a difference between the amplitude and the average intensity.

In some embodiments, the overlay value is further determined based on a bias of the first and second metrology marks relative to each other.

In some embodiments, the first amplitude is associated with a segment of a metrology mark with a positive bias and the second amplitude is associated with a segment of a metrology mark with a negative bias of the first and second metrology marks relative to each other. In some embodiments, the first amplitude is associated with a positive bias and the second amplitude is associated with a negative bias of the entire first and second metrology marks relative to each other.

In some embodiments, the average intensity of fringes is sensitive to surrounding structures in the first and second layers of the patterned substrate.

In some embodiments, the first and second metrology marks comprise a size that is the same as or larger than a C16 or C20 μDBO mark.

In some embodiments, determining the overlay value does not require a calibration factor.

In some embodiments, the overlay metrology system is configured for first performing one or more of the operations described above to determine the calibration factor, and then performing other operations using metrology marks that are smaller than a C16 or C20 μDBO mark.

In some embodiments, the one or more processors are configured such that: determining the one or more parameters of the fringes comprises determining an amplitude and a phase of fringes in the filtered intensity modulated fringe pattern; and determining the overlay value is based on the amplitude and the phase.

In some embodiments, determining the phase comprises determining a phase difference between: (1) diffracted radiation received from first corresponding top and bottom segments of the first and second metrology mark in the first and second layer of the patterned substrate, and (2) diffracted radiation received from second corresponding top and bottom segments of the first and second metrology mark. In some embodiments, the phase difference comprises information indicative of a reciprocal optical strength of the first and second metrology marks, and overlay is determined at least in part based on the reciprocal optical strength.

In some embodiments, the first and second corresponding top and bottom segments are spaced from each other by a known distance, and overlay is determined at least in part based on the phase difference and the known distance.

In some embodiments, the reciprocal optical strength is used by the one or more processors to determine a calibration factor that relates the amplitudes to the overlay value, and determine overlay based on the amplitude and the calibration factor. In some embodiments, determining the overlay value does not require a calibration factor.

In some embodiments, determining the amplitude comprises determining a first amplitude associated with a segment of a metrology mark with a positive bias, and a second amplitude associated with a segment of a metrology mark with a negative bias, of the first and second metrology marks relative to each other; and determining the phase comprises determining a first phase associated with the segment of the metrology mark with the positive bias, and a second phase associated with the segment of a metrology mark with the negative bias.

In some embodiments, the one or more processors are configured to determine complex amplitudes based on the first and second amplitudes and the first and second phases, determine a real portion of the complex amplitudes, and determine overlay based on the real portion and the positive and negative biases.

In some embodiments, the one or more processors are configured to determine a scaling factor based on the first and second amplitudes, determine a phase factor based on the first and second phases, and determine overlay based on the scaling factor and the phase factor. In some embodiments, determining overlay based on the scaling factor and the phase factor comprises solving a system of two non-linear equations, with one non-linear equation each associated with the scaling factor and the phase factor, and a variable common between the two non-linear equations comprising overlay.

In some embodiments, the metrology signal is configured to be used by the one or more processors to adjust a semiconductor device manufacturing process.

According to another embodiment, a metrology method comprising one or more of the operations described above is provided.

### BRIEF DESCRIPTION OF THE DRAWINGS

The above aspects and other aspects and features will become apparent to those ordinarily skilled in the art upon review of the following description of specific embodiments in conjunction with the accompanying figures.

FIG. 1 schematically depicts a lithography apparatus, according to an embodiment.

FIG. 2 schematically depicts an embodiment of a lithographic cell or cluster, according to an embodiment.

FIG. 3 schematically depicts an example metrology system, according to an embodiment.

FIG. 4 schematically depicts an example metrology technique, according to an embodiment.

FIG. 5 illustrates the relationship between a radiation illumination spot of an inspection system and a metrology target, according to an embodiment.

FIG. 6 illustrates an overlay metrology method, according to an embodiment.

FIG. 7 schematically depicts another example metrology system, according to an embodiment.

FIG. 8 illustrates an example of a fringe pattern, which can be used to determine overlay, according to an embodiment.

FIG. 9 illustrates a first amplitude and a second amplitude of fringes in a filtered intensity modulated fringe pattern, according to an embodiment.

FIG. 10 illustrates determination of overlay (e.g., an overlay value) based on amplitude(s) from a fringe pattern such as the fringe pattern shown in FIG. 9, according to an embodiment.

FIG. 11 illustrates determination of overlay (e.g., an overlay value) based on amplitude(s) and phase(es) from a fringe pattern such as the fringe pattern shown in FIG. 9, according to an embodiment.

FIG. 12 illustrates a metrology system with a different configuration, along with a fringe pattern and associated images for different diffraction orders.

FIG. 13 is a block diagram of an example computer system, according to an embodiment.

### DETAILED DESCRIPTION

In semiconductor device manufacturing, determining overlay typically includes determining the (relative) positions of different metrology marks of a metrology target, such as a diffraction based overlay target, in different layers of a semiconductor device structure. In order to meet smaller and smaller node sizes, and/or to make more efficient use of limited substrate real estate, smaller and smaller metrology (overlay, etc.) targets, multi-purpose targets (e.g., one metrology target that can be used for both overlay and alignment), and/or other space saving techniques are needed. Smaller targets and/or targets that can be used for multiple purposes facilitate a need for less targets, placement of targets in a field with a limited area, placement of targets closer to the edges of a substrate, and/or other advantages.

Existing metrology systems often utilize separate sensors and metrology targets for overlay and alignment operations. This can cause differences between aligned position and overlay, even when measuring the same marks, which can degrade On Product Overlay (OPO) and/or have other negative effects. Also, current overlay measurement solutions are sensitive to surrounding structures, so that more real estate on a substrate is required for a given overlay target and/or an overlay target may be more difficult to place on a substrate among the surrounding structures because of the sensitivity to scattering from the surrounding structures. For example, an overlay target may be made large so that a region of interest within the target, surrounded by a buffer portion of the target that separates the region of interest from other structures beyond the target, may be used. As another example, an overlay target may be placed some distance away from other structures on a substrate.

In contrast to prior systems, the present systems and methods are configured for determining overlay using a microscope based sensor, therefore being able to determine alignment and overlay with a single system, and using the same physical target for alignment, overlay, and/or other metrology operations. The present systems and methods may also use smaller marks, and/or marks positioned relatively close to other structures in a substrate, for determining overlay.

The present systems and methods have these and other advantages because the signal from the sensor is an intensity modulated fringe pattern (e.g., an interference pattern). The sensor is configured to generate the intensity modulated fringe pattern based on diffracted radiation received from a first metrology mark in a first layer of a patterned substrate and a second metrology mark in a second layer of the patterned substrate (the first and second marks together comprising an overlay target). In the present systems and methods, the intensity modulated fringe pattern is filtered for an expected fringe period, and amplitude, phase, and/or other parameters of fringes of the filtered fringe pattern are used to determine an overlay value. The present systems and methods are more robust to the presence of neighboring structures in a substrate when determining overlay compared to prior systems because they use the amplitude(s) and/or phases (or phase differences) of fringes to determine overlay, as described herein (e.g., instead of images and/or other data used in prior overlay determination techniques).

By way of a brief introduction, the following description relates generally to semiconductor device manufacturing and patterning processes. More particularly, the following paragraphs describe several components of a system and/or related systems. As described above these systems and methods may be used for measuring overlay in a semiconductor device manufacturing process, for example, or for other operations.

Although specific reference may be made in this text to the measurement of overlay and the manufacture of integrated circuits (ICs) for semiconductor devices, it should be understood that the description has many other possible applications. For example, it may be employed in the measurement of other parameters. It may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

The term “projection optics” should be broadly interpreted as encompassing various types of optical systems, including refractive optics, reflective optics, apertures and catadioptric optics, for example. The term “projection optics” may also include components operating according to any of these design types for directing, shaping or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device. The projection optics generally exclude the source and the patterning device.

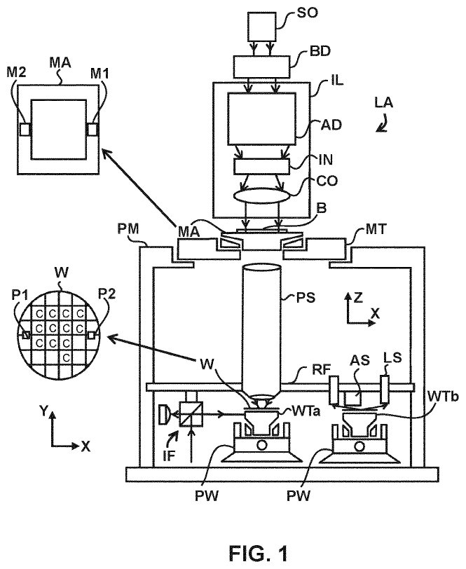

FIG. 1 schematically depicts an embodiment of a lithographic apparatus LA. The apparatus comprises an illumination system (illuminator) IL configured to condition a radiation beam B (e.g. UV radiation, DUV radiation, or EUV radiation); a support structure (e.g. a mask table) MT constructed to support a patterning device (e.g. a mask) MA and connected to a first positioner PM configured to accurately position the patterning device in accordance with certain parameters; a substrate table (e.g. a wafer table) WT (e.g., WTa, WTb or both) configured to hold a substrate (e.g. a resist-coated wafer) W and coupled to a second positioner PW configured to accurately position the substrate in accordance with certain parameters; and a projection system (e.g. a refractive projection lens system) PS configured to project a pattern imparted to the radiation beam B by patterning device MA onto a target portion C (e.g. comprising one or more dies and often referred to as fields) of the substrate W. The projection system is supported on a reference frame RF. As depicted, the apparatus is of a transmissive type (e.g., employing a transmissive mask). Alternatively, the apparatus may be of a reflective type (e.g., employing a programmable mirror array, or employing a reflective mask).

The illuminator IL receives a beam of radiation from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising for example suitable directing mirrors and/or a beam expander. In other cases, the source may be an integral part of the apparatus, for example when the source is a mercury lamp. The source SO and the illuminator IL, together with the beam delivery system BD if required, may be referred to as a radiation system.

The illuminator IL may alter the intensity distribution of the beam. The illuminator may be arranged to limit the radial extent of the radiation beam such that the intensity distribution is non-zero within an annular region in a pupil plane of the illuminator IL. Additionally, or alternatively, the illuminator IL may be operable to limit the distribution of the beam in the pupil plane such that the intensity distribution is non-zero in a plurality of equally spaced sectors in the pupil plane. The intensity distribution of the radiation beam in a pupil plane of the illuminator IL may be referred to as an illumination mode.

The illuminator IL may comprise adjuster AD configured to adjust the (angular/spatial) intensity distribution of the beam. Generally, at least the outer and/or inner radial extent (commonly referred to as σ-outer and σ-inner, respectively) of the intensity distribution in a pupil plane of the illuminator can be adjusted. The illuminator IL may be operable to vary the angular distribution of the beam. For example, the illuminator may be operable to alter the number, and angular extent, of sectors in the pupil plane where the intensity distribution is non-zero. By adjusting the intensity distribution of the beam in the pupil plane of the illuminator, different illumination modes may be achieved. For example, by limiting the radial and angular extent of the intensity distribution in the pupil plane of the illuminator IL, the intensity distribution may have a multi-pole distribution such as, for example, a dipole, quadrupole or hexapole distribution. A desired illumination mode may be obtained, e.g., by inserting an optic which provides that illumination mode into the illuminator IL or using a spatial light modulator.

The illuminator IL may be operable to alter the polarization of the beam and may be operable to adjust the polarization using adjuster AD. The polarization state of the radiation beam across a pupil plane of the illuminator IL may be referred to as a polarization mode. The use of different polarization modes may allow greater contrast to be achieved in the image formed on the substrate W. The radiation beam may be unpolarized. Alternatively, the illuminator may be arranged to linearly polarize the radiation beam. The polarization direction of the radiation beam may vary across a pupil plane of the illuminator IL. The polarization direction of radiation may be different in different regions in the pupil plane of the illuminator IL. The polarization state of the radiation may be chosen in dependence on the illumination mode. For multi-pole illumination modes, the polarization of each pole of the radiation beam may be generally perpendicular to the position vector of that pole in the pupil plane of the illuminator IL. For example, for a dipole illumination mode, the radiation may be linearly polarized in a direction that is substantially perpendicular to a line that bisects the two opposing sectors of the dipole. The radiation beam may be polarized in one of two different orthogonal directions, which may be referred to as X-polarized and Y-polarized states. For a quadrupole illumination mode, the radiation in the sector of each pole may be linearly polarized in a direction that is substantially perpendicular to a line that bisects that sector. This polarization mode may be referred to as XY polarization. Similarly, for a hexapole illumination mode the radiation in the sector of each pole may be linearly polarized in a direction that is substantially perpendicular to a line that bisects that sector. This polarization mode may be referred to as TE polarization.

In addition, the illuminator IL generally comprises various other components, such as an integrator IN and a condenser CO. The illumination system may include various types of optical components, such as refractive, reflective, magnetic, electromagnetic, electrostatic or other types of optical components, or any combination thereof, for directing, shaping, or controlling radiation.

Thus, the illuminator provides a conditioned beam of radiation B, having a desired uniformity and intensity distribution in its cross section.

The support structure MT supports the patterning device in a manner that depends on the orientation of the patterning device, the design of the lithographic apparatus, and other conditions, such as for example whether or not the patterning device is held in a vacuum environment. The support structure may use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system. Any use of the terms “reticle” or “mask” may be considered synonymous with the more general term “patterning device.”

The term “patterning device” should be broadly interpreted as referring to any device that can be used to impart a pattern in a target portion of the substrate. In an embodiment, a patterning device is any device that can be used to impart a radiation beam with a pattern in its cross-section to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in a target portion of the device, such as an integrated circuit.

A patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted to reflect an incoming radiation beam in different directions. The tilted mirrors impart a pattern in a radiation beam, which is reflected by the mirror matrix.

The term “projection system” should be broadly interpreted as encompassing any type of projection system, including refractive, reflective, catadioptric, magnetic, electromagnetic, and electrostatic optical systems, or any combination thereof, as appropriate for the exposure radiation being used, or for other factors such as the use of an immersion liquid or the use of a vacuum. Any use of the term “projection lens” may be considered as synonymous with the more general term “projection system”.

The projection system PS may comprise a plurality of optical (e.g., lens) elements and may further comprise an adjustment mechanism configured to adjust one or more of the optical elements to correct for aberrations (phase variations across the pupil plane throughout the field). To achieve this, the adjustment mechanism may be operable to manipulate one or more optical (e.g., lens) elements within the projection system PS in one or more different ways. The projection system may have a co-ordinate system where its optical axis extends in the z direction. The adjustment mechanism may be operable to do any combination of the following: displace one or more optical elements; tilt one or more optical elements; and/or deform one or more optical elements. Displacement of an optical element may be in any direction (x, y, z, or a combination thereof). Tilting of an optical element is typically out of a plane perpendicular to the optical axis, by rotating about an axis in the x and/or y directions although a rotation about the z axis may be used for a non-rotationally symmetric aspherical optical element. Deformation of an optical element may include a low frequency shape (e.g., astigmatic) and/or a high frequency shape (e.g., free form aspheres). Deformation of an optical element may be performed for example by using one or more actuators to exert force on one or more sides of the optical element and/or by using one or more heating elements to heat one or more selected regions of the optical element. In general, it may not be possible to adjust the projection system PS to correct for apodization (transmission variation across the pupil plane). The transmission map of a projection system PS may be used when designing a patterning device (e.g., mask) MA for the lithography apparatus LA. Using a computational lithography technique, the patterning device MA may be designed to at least partially correct for apodization.

The lithographic apparatus may be of a type having two (dual stage) or more tables (e.g., two or more substrate tables WTa, WTb, two or more patterning device tables, a substrate table WTa and a table WTb below the projection system without a substrate that is dedicated to, for example, facilitating measurement, and/or cleaning, etc.). In such “multiple stage” machines, the additional tables may be used in parallel, or preparatory steps may be carried out on one or more tables while one or more other tables are being used for exposure. For example, alignment measurements using an alignment sensor AS and/or level (height, tilt, etc.) measurements using a level sensor LS may be made.

In operation of the lithographic apparatus, a radiation beam is conditioned and provided by the illumination system IL. The radiation beam B is incident on the patterning device (e.g., mask) MA, which is held on the support structure (e.g., mask table) MT, and is patterned by the patterning device. Having traversed the patterning device MA, the radiation beam B passes through the projection system PS, which focuses the beam onto a target portion C of the substrate W. With the aid of the second positioner PW and position sensor IF (e.g., an interferometric device, linear encoder, 2-D encoder or capacitive sensor), the substrate table WT can be moved accurately, e.g., to position different target portions C in the path of the radiation beam B. Similarly, the first positioner PM and another position sensor (which is not explicitly depicted in FIG. 1) can be used to accurately position the patterning device MA with respect to the path of the radiation beam B, e.g., after mechanical retrieval from a mask library, or during a scan. In general, movement of the support structure MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner), the support structure MT may be connected to a short-stroke actuator only or may be fixed. Patterning device MA and substrate W may be aligned using patterning device alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device MA, the patterning device alignment marks may be located between the dies.

The depicted apparatus may be used in at least one of the following modes. In step mode, the support structure MT and the substrate table WT are kept essentially stationary, while a pattern imparted to the radiation beam is projected onto a target portion C at one time (i.e., a single static exposure). The substrate table WT is then shifted in the X and/or Y direction so that a different target portion C can be exposed. In step mode, the maximum size of the exposure field limits the size of the target portion C imaged in a single static exposure. In scan mode, the support structure MT and the substrate table WT are scanned synchronously while a pattern imparted to the radiation beam is projected onto a target portion C (i.e., a single dynamic exposure). The velocity and direction of the substrate table WT relative to the support structure MT may be determined by the (de-) magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion. In another mode, the support structure MT is kept essentially stationary holding a programmable patterning device, and the substrate table WT is moved or scanned while a pattern imparted to the radiation beam is projected onto a target portion C. In this mode, generally a pulsed radiation source is employed, and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above-described modes of use or entirely different modes of use may also be employed.

The substrate may be processed, before or after exposure, in for example a track (a tool that typically applies a layer of resist to a substrate and develops the exposed resist) or a metrology or inspection tool. Where applicable, the disclosure may be applied to such and other substrate processing tools. Further, the substrate may be processed more than once, for example in order to create a multi-layer IC, so that the term substrate may also refer to a substrate that already includes multiple processed layers.

The terms “radiation” and “beam” used with respect to lithography encompass all types of electromagnetic radiation, including ultraviolet (UV) or deep ultraviolet (DUV) radiation (e.g., having a wavelength of 365, 248, 193, 157 or 126 nm) and extreme ultra-violet (EUV) radiation (e.g., having a wavelength in the range of 5-20 nm), as well as particle beams, such as ion beams or electron beams.

Various patterns on or provided by a patterning device may have different process windows. i.e., a space of processing variables under which a pattern will be produced within specification. Examples of pattern specifications that relate to potential systematic defects include checks for necking, line pull back, line thinning, CD, edge placement, overlapping, resist top loss, resist undercut and/or bridging. The process window of the patterns on a patterning device or an area thereof may be obtained by merging (e.g., overlapping) process windows of each individual pattern. The boundary of the process window of a group of patterns comprises boundaries of process windows of some of the individual patterns. In other words, these individual patterns limit the process window of the group of patterns.

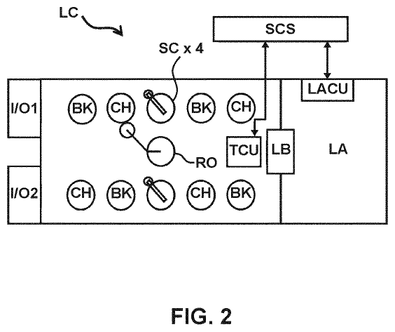

As shown in FIG. 2, the lithographic apparatus LA may form part of a lithographic cell LC, also sometimes referred to a lithocell or cluster, which also includes apparatuses to perform pre-and post-exposure processes on a substrate. Conventionally these include one or more spin coaters SC to deposit one or more resist layers, one or more developers to develop exposed resist, one or more chill plates CH and/or one or more bake plates BK. A substrate handler, or robot, RO picks up one or more substrates from input/output port I/O1, I/O2, moves them between the different process apparatuses and delivers them to the loading bay LB of the lithographic apparatus. These apparatuses, which are often collectively referred to as the track, are under the control of a track control unit TCU which is itself controlled by the supervisory control system SCS, which also controls the lithographic apparatus via lithography control unit LACU. Thus, the different apparatuses can be operated to maximize throughput and processing efficiency.

In order that a substrate that is exposed by the lithographic apparatus is exposed correctly and consistently and/or in order to monitor a part of the patterning process (e.g., a device manufacturing process) that includes at least one pattern transfer step (e.g., an optical lithography step), it is desirable to inspect a substrate or other object to measure or determine one or more properties such as alignment, overlay (which can be, for example, between structures in overlying layers or between structures in a same layer that have been provided separately to the layer by, for example, a double patterning process), line thickness, critical dimension (CD), focus offset, a material property, etc. Accordingly, a manufacturing facility in which lithocell LC is located also typically includes a metrology system that measures some or all of the substrates W (FIG. 1) that have been processed in the lithocell or other objects in the lithocell. The metrology system may be part of the lithocell LC, for example it may be part of the lithographic apparatus LA (such as alignment sensor AS (FIG. 1)).

The one or more measured parameters may include, for example, overlay between successive layers formed in or on the patterned substrate, alignment, critical dimension (CD) (e.g., critical linewidth) of, for example, features formed in or on the patterned substrate, focus or focus error of an optical lithography step, dose or dose error of an optical lithography step, optical aberrations of an optical lithography step, etc. This measurement is often performed on a dedicated metrology target provided on the substrate. The measurement can be performed after-development of a resist but before etching, after-etching, after deposition, and/or at other times.

There are various techniques for making measurements of the structures formed in the patterning process, including the use of a scanning electron microscope, an image-based measurement tool and/or various specialized tools. A fast and non-invasive form of specialized metrology tool is one in which a beam of radiation is directed onto a target on the surface of the substrate and properties of the scattered (diffracted/reflected) beam are measured. By evaluating one or more properties of the radiation scattered by the substrate, one or more properties of the substrate can be determined.

Traditionally, this may be termed diffraction-based metrology. One such application of this diffraction-based metrology is in the measurement of overlay (e.g., as described below).

Thus, in a device fabrication process (e.g., a patterning process or a lithography process), a substrate or other objects may be subjected to various types of measurement during or after the process. The measurement may determine whether a particular substrate is defective, may establish adjustments to the process and apparatuses used in the process (e.g., aligning two or more layers on the substrate or aligning the patterning device to the substrate), may measure the performance of the process and the apparatuses, or may be for other purposes. Examples of measurement include optical imaging (e.g., optical microscope), non-imaging optical measurement (e.g., measurement based on diffraction such as the ASML YieldStar metrology tool, the ASML SMASH metrology system), mechanical measurement (e.g., profiling using a stylus, atomic force microscopy (AFM)), and/or non-optical imaging (e.g., scanning electron microscopy (SEM)).

Metrology results may be provided directly or indirectly to the supervisory control system SCS. If an error is detected, an adjustment may be made to exposure of a subsequent substrate (especially if the inspection can be done soon and fast enough that one or more other substrates of the batch are still to be exposed) and/or to subsequent exposure of the exposed substrate. Also, an already exposed substrate may be stripped and reworked to improve yield, or discarded, thereby avoiding performing further processing on a substrate known to be faulty. In a case where only some target portions of a substrate are faulty, further exposures may be performed only on those target portions which meet specifications. Other manufacturing process adjustments are contemplated.

A metrology system may be used to determine one or more properties of the substrate structure, and in particular, how one or more properties of different substrate structures vary, or different layers of the same substrate structure vary from layer to layer. The metrology system may be integrated into the lithographic apparatus LA or the lithocell LC, or may be a stand-alone device.

To enable the metrology, often one or more targets are specifically provided on the substrate. A target may include an overlay target, for example, an alignment mark, and/or other targets. Typically, the target is specially designed and may comprise one or more periodic structures. For example, the target on a substrate may comprise one or more 1-D periodic structures (e.g., geometric features such as gratings) in one or more layers of the substrate, which are printed such that after development, the periodic structural features are formed of solid resist lines. As another example, the target may comprise one or more 2-D periodic structures (e.g., gratings) in one or more layers, which are printed such that after development, the one or more periodic structures are formed of solid resist pillars or vias in the resist. The bars, pillars, or vias may alternatively be etched into the substrate (e.g., into one or more layers on the substrate).

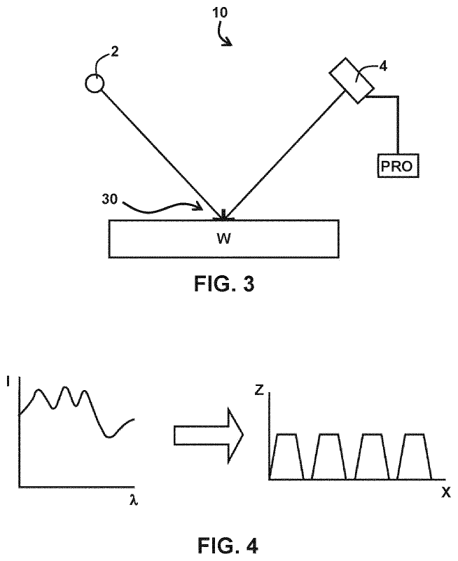

FIG. 3 depicts an example inspection (metrology) system 10 that may be used to detect overlay, alignment, and/or perform other metrology operations. It comprises a radiation source 2 which projects or otherwise irradiates radiation onto a substrate W. Substrate W may typically include a metrology target 30 such as an overlay target, an alignment mark, and/or other structures. The redirected radiation is passed to a radiation sensor such as a spectrometer detector 4 and/or other sensors, which measures a spectrum (intensity as a function of wavelength) of the specular reflected and/or diffracted radiation, as shown, e.g., in the graph on the left of FIG. 4. The sensor may generate a metrology signal conveying overlay data, alignment data, and/or other data indicative of properties of the reflected radiation. From this data, the structure or profile giving rise to the detected spectrum may be reconstructed by one or more processors PRO, a generalized example of which is shown in FIG. 4, or by other operations. Note that these are generalized examples. Often, illumination of a target such as overlay target and/or an alignment mark is done orthogonal to the target and/or mark, and not at an angle as shown in FIG. 3.

As in the lithographic apparatus LA in FIG. 1, one or more substrate tables (not shown in FIG. 4) may be provided to hold the substrate W during metrology operations. The one or more substrate tables may be similar or identical in form to the substrate table WT (WTa or WTb or both) of FIG. 1. In an example where inspection system 10 is integrated with the lithographic apparatus, they may even be the same substrate table. Coarse and fine positioners may be provided and configured to accurately position the substrate in relation to a measurement optical system. Various sensors and actuators are provided, for example, to acquire the position of a target portion of interest of a structure (e.g., an overlay target and/or an alignment mark), and to bring it into position under an objective lens. Typically, many measurements will be made on target portions of a structure at different locations across the substrate W. The substrate support can be moved in X and Y directions to acquire different targets, and in the Z direction to obtain a desired location of the target portion relative to the focus of the optical system. It is convenient to think and describe operations as if the objective lens is being brought to different locations relative to the substrate, when, for example, in practice the optical system may remain substantially stationary (typically in the X and Y directions, but perhaps also in the Z direction) and the substrate moves. Provided the relative position of the substrate and the optical system is correct, it does not matter in principle which one of those is moving, or if both are moving, or a combination of a part of the optical system is moving (e.g., in the Z and/or tilt direction) with the remainder of the optical system being stationary and the substrate is moving (e.g., in the X and Y directions, but also optionally in the Z and/or tilt direction).

For typical metrology measurements, a target 30 on substrate W may be a 1-D grating, which is printed such that after development, the bars are formed of solid resist lines (e.g., which may be covered by a deposition layer), and/or other materials. Or the target 30 may be a 2-D grating, which is printed such that after development, the grating is formed of solid resist pillars, and/or other features in the resist. The bars, pillars, vias, and/or other features may be etched into or on the substrate (e.g., into one or more layers on the substrate), deposited on a substrate, covered by a deposition layer, and/or have other properties. Target 30 (e.g., of bars, pillars, vias, etc.) is sensitive to changes in processing in the patterning process (e.g., optical aberration in the lithographic projection apparatus such as in the projection system, focus change, dose change, etc.) such that process variation manifests in variation in target 30. Accordingly, the measured data from target 30 may be used to determine an adjustment for one or more of the manufacturing processes, and/or used as a basis for making the actual adjustment. Note that in this example, target 30 may represent one or more layers comprising one or more metrology targets.

For example, the measured data from target 30 may indicate overlay for layers of a semiconductor device, alignment, and/or other information. The measured data from target 30 may be used (e.g., by the one or more processors) for determining one or more semiconductor device manufacturing process parameters based the alignment, overlay, and/or other information, and/or determining an adjustment for a semiconductor device manufacturing apparatus based on the one or more determined semiconductor device manufacturing process parameters. In some embodiments, this may comprise a stage position adjustment, for example, or this may include determining an adjustment for a mask design, a metrology target (e.g., an overlay target and/or an alignment mark) design, a semiconductor device design, an intensity of the radiation, an incident angle of the radiation, a wavelength of the radiation, a pupil size and/or shape, a resist material, and/or other process parameters.

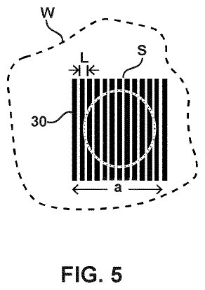

FIG. 5 illustrates a plan view of a typical target 30 (e.g., an overlay target, an alignment mark, etc.), and the extent of a radiation illumination spot S in the system of FIG. 4. Typically, to obtain a diffraction spectrum that is free of interference from surrounding structures, the target 30, in an embodiment, comprises one or more periodic structures (e.g., gratings) larger than the width (e.g., diameter) of the illumination spot S. The width of spot S may be smaller than the width and length of the target 30. The target 30, in other words, is ‘underfilled’ by the illumination, and the diffraction signal is essentially free from any signals from product features and the like outside the target itself. The illumination arrangement may be configured to provide illumination of a uniform intensity across a back focal plane of an objective, for example. Alternatively, by, for example, including an aperture in the illumination path, illumination may be restricted to on axis or off axis directions.

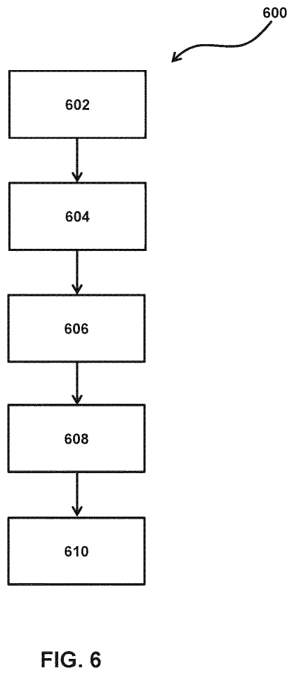

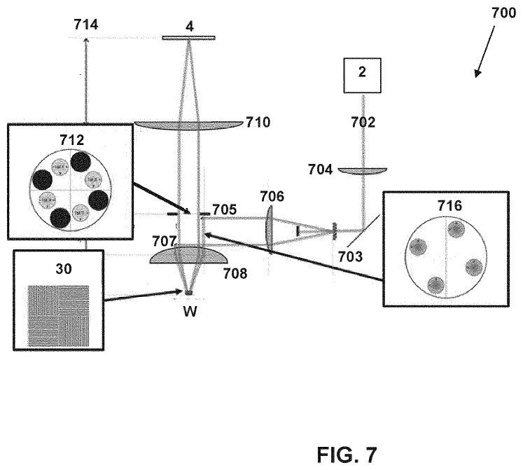

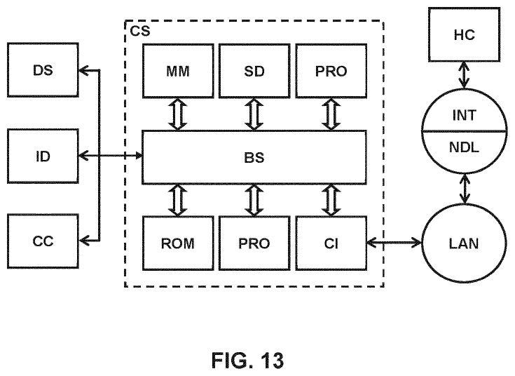

FIG. 6 illustrates an overlay metrology method 600. In some embodiments, method 600 is performed as part of a semiconductor device manufacturing process. In some embodiments, one or more operations of method 600 may be implemented in or by system 10 illustrated in FIGS. 3 and 4 (and FIG. 7 described below), a computer system (e.g., as illustrated in FIG. 13 and described below), and/or in or by other systems, for example. In some embodiments, method 600 comprises irradiating (operation 602) a metrology target in a patterned substrate (such as a semiconductor wafer) with radiation, generating (operation 604) a metrology signal based on received radiation from the metrology mark, filtering (operation 606) the metrology signal, determining (operation 608) one or more parameters based on the filtered metrology signal, determining (operation 610) an overlay value based on the one or more parameters and/or other information, and/or other operations. Method 600 is described below in the context of overlay, but this is not intended to be limiting. Method 600 may be generally applied to a number of different processes.

The operations of method 600 presented below are intended to be illustrative. In some embodiments, method 600 may be accomplished with one or more additional operations not described, and/or without one or more of the operations discussed. For example, in some embodiments, method 600 may include an additional operation comprising determining an adjustment for a semiconductor device manufacturing process. Additionally, the order in which the operations of method 600 are illustrated in FIG. 6 and described below is not intended to be limiting.

In some embodiments, one or more portions of method 600 may be implemented in and/or controlled by one or more processing devices (e.g., a digital processor, an analog processor, a digital circuit designed to process information, an analog circuit designed to process information, a state machine, and/or other mechanisms for electronically processing information-see the description of processors PRO). The one or more processing devices may include one or more devices executing some or all of the operations of method 600 in response to (machine readable) instructions stored electronically on an electronic storage medium. The one or more processing devices may include one or more devices configured through hardware, firmware, and/or software to be specifically designed for execution of one or more of the operations of method 600 (e.g., see discussion related to FIG. 13 below).

Operation 602 comprises irradiating a metrology target in a patterned substrate with radiation. In some embodiments, the metrology target comprises metrology marks in different layers of the patterned substrate, and/or other features. In some embodiments, the metrology target is associated with an alignment and/or overlay measurement for the patterned substrate. For example, the metrology target may be or include a dedicated overlay target comprising diffraction gratings in the different layers. The radiation may be diffracted by the diffraction grating(s). In some embodiments, the metrology target comprises one or more structures in the patterned substrate capable of providing a diffraction signal (e.g., a metrology target or some other structure(s)). In some embodiments, the metrology target can be any structure in a pattern design layout capable of generating a wide-angle diffraction signal.

In some embodiments, the metrology target may be included in one or more layers of a substrate in a semiconductor device structure, for example. In some embodiments, the metrology target comprises one or more geometric features such as 1D or 2D features, and/or other geometric features. By way of several non-limiting examples, a metrology target may comprise a line, an edge, a fine-pitched series of lines and/or edges, a set of multiple fine-pitched series of lines and/or edges, and/or other features.

In some embodiments, the radiation source (e.g., source 2 shown in FIG. 3) is configured to irradiate a metrology target comprising a first metrology mark in a first layer of a patterned substrate and a second metrology mark in a second layer of the patterned substrate with radiation. In some embodiments, the second metrology mark is directly above the first metrology mark in the patterned substrate in a second layer of a semiconductor structure, though the first metrology mark in the first layer may be shifted relative to the second metrology mark by a known bias amount.

In some embodiments, the first and second metrology marks comprise a diffraction-based overlay metrology mark such as a grating and/or other metrology marks. The gratings may have the same pitch, different pitches, and/or other features. In some embodiments, the first and second metrology marks (or any two metrology marks in different layers) form a Micro Diffraction Based Overlay (μDBO) target, with the first and second metrology marks comprising gratings in the first and second layers of the patterned substrate.

The radiation may have a target wavelength and/or wavelength range, a target intensity, and/or other characteristics. The target wavelength and/or wavelength range, the target intensity, etc., may be entered and/or selected by a user, determined by the system based on previous metrology measurements, and/or determined in other ways. In some embodiments, the radiation comprises light and/or other radiation. In some embodiments, the light comprises visible light, infrared light, near infrared light, and/or other light. In some embodiments, the radiation may be any radiation appropriate for interferometry.

The radiation may be generated by a radiation source (e.g., source 2 shown in FIGS. 3 and 4 and described above) and/or other components. In some embodiments, the radiation may be directed by the radiation source (e.g., by way of one or more lenses, a modulator, and/or other components) onto a metrology target, sub-portions (e.g., something less than the whole) of a metrology target, multiple metrology targets, and/or onto the substrate in other ways. In some embodiments, radiation from the radiation source is on axis or off axis. Off axis may allow for a larger wavelength pitch compatibility than on axis. Conjugate diffracted orders that can interfere with each other are desired. In On-axis Illumination (e.g., normal dark field microscopy) there may be almost 50% less wavelength pitch coverage than off-axis illumination. In some embodiments, radiation from the radiation source is spatially incoherent or spatially coherent. For example, assuming a target is illuminated all at once (stationary) with an illumination spot, microscopy with a spatially incoherent light source may be preferred to avoid interferometric cross talk with e.g., surroundings (e.g., speckle). Using spatially coherent light may require compensating for this cross-talk with, e.g., holographic and/or other methods. Spatially incoherent light may be preferred because of its robustness. However, spatially coherent light may be used after correcting the coherent artifacts.

In some embodiments, the metrology target may be substantially stationary while irradiation occurs, the radiation sensor generates the metrology signal, an image of the metrology target is generated based on the metrology signal and/or other information, and/or other operations are performed. In some embodiments, the radiation may be scanned across a metrology target, for example. Scanning may comprise rastering the radiation over a metrology target such that different portions of the metrology target are irradiated at different times. In some embodiments, characteristics of the radiation (e.g., wavelength, intensity, etc.) may be varied by the radiation source over time (whether in a stationary or a scanning mode). This may create and/or supplement time varying radiation for analysis. This may also facilitate analysis of individual portions of a feature, comparison of one portion of a feature to another and/or to other features, and/or other analysis.

Operation 604 comprises generating a metrology signal based on received radiation from a metrology target (e.g., from the first and second metrology marks described above), and/or other information. The metrology signal may be generated by a radiation sensor (e.g., such as sensor detector 4 shown in 3) and/or other components. The radiation sensor may comprise an interferometric microscopy detector, such as an interferometric microscope-based alignment sensor. In some embodiments, the radiation sensor may comprise a camera, and/or other components, for example.

Operation 604 includes detecting reflected and/or transmitted radiation from the metrology target. In some embodiments, the metrology signal comprises overlay and/or alignment position information for the first and second layers conveyed by the reflected and/or transmitted radiation from the metrology target.

Detecting such radiation comprises detecting intensity shifts in (diffracted) radiation received from one or more geometric features. The one or more phase and/or amplitude shifts correspond to one or more dimensions of a feature. For example, the phase and/or amplitude of reflected radiation from one side of a feature is different relative to the phase and/or amplitude of reflected radiation from another side of the feature. Detecting the one or more phase and/or amplitude (intensity) shifts in the radiation from the metrology mark comprises measuring local phase shifts (e.g., local phase deltas) and/or amplitude variations that correspond to different portions of a metrology mark. For example, the radiation from a specific area of a mark may comprise a sinusoidal waveform having a certain phase and/or amplitude. The radiation from a different area of the mark may also comprise a sinusoidal waveform, but one with a different phase and/or amplitude. Detecting radiation also comprises measuring a phase and/or amplitude difference in radiation of different diffraction orders. Detecting the one or more local phase and/or amplitude shifts may be performed using Fourier transformations, Hilbert transformations, for example, and/or other techniques. Interferometry techniques and/or other operations may be used to measure phase and/or amplitude differences in reflected radiation of different diffraction orders.

The metrology signal comprises measurement information pertaining to the metrology target. For example, the metrology signal may be an alignment signal comprising alignment measurement information, an overlay signal comprising overlay measurement information, and/or other metrology signals. In some embodiments, operation 604 includes determining, based on the metrology signal, overlay for one or more layers of the semiconductor layer structure. The measurement information may be determined using principles of interferometry and/or other principles.

The metrology signal comprises an electronic signal that represents and/or otherwise corresponds to the radiation from a metrology target. The metrology signal may indicate an overlay value for one or more layers, for example, an alignment value, and/or other information. Generating the metrology signal comprises sensing the radiation and converting the sensed radiation into the electronic signal. In some embodiments, generating the metrology signal comprises sensing different portions of the radiation from different portions and/or different geometries of the metrology target (e.g., different gratings in different layers), and combining the different portions of the sensed radiation to form the metrology signal. This sensing and converting may be performed by components similar to and/or the same as radiation sensor detector 4 and/or processors PRO shown in FIG. 3, FIG. 4, and FIG. 13, and/or other components.

As described above, the metrology target is configured to diffract radiation from the source. The radiation received by the radiation sensor comprises diffracted radiation. The metrology signal comprises an intensity modulated fringe pattern for diffracted radiation received from the metrology target. In some embodiments, the intensity modulated fringe pattern comprises a one or more dimensional interference pattern. In some embodiments, the radiation sensor is configured such that the intensity modulated fringe pattern for the diffracted radiation comprises an interference pattern generated based on diffracted radiation from the first metrology mark and the second metrology mark.

At operation 606, the metrology signal (e.g., the intensity modulated fringe pattern described above) is filtered. At operation 608, one or more parameters are determined based on the filtered metrology signal and or other information. At operation 610, an overlay value is determined based on the one or more parameters and/or other information. Operations 606, 608, and/or 610 may be performed by one or more processors PRO (see FIG. 3, FIG. 13), and/or other components.

The one or more processors PRO are configured such that the intensity modulated fringe pattern is filtered for an expected fringe period. The expected fringe period is determined based on the pitch of the first and/or second metrology marks (e.g., gratings, which have the same pitch, as described above), and/or other information. The one or more processors PRO are configured to determine one or more parameters of fringes in the intensity modulated fringe pattern based on the filtered intensity modulated fringe pattern, and/or other information.

In some embodiments, the one or more processors are configured such that determining the one or more parameters of the fringes comprises determining a first amplitude and a second amplitude of fringes in the filtered intensity modulated fringe pattern. In some embodiments, the first amplitude is associated with a positive bias and the second amplitude is associated with a negative bias of the first and second metrology marks relative to each other. In some embodiments, the first amplitude is associated with a segment of a metrology mark with a positive bias and the second amplitude is associated with a segment of a metrology mark with a negative bias of the first and second metrology marks relative to each other. In some embodiments, the first amplitude is associated with a positive bias and the second amplitude is associated with a negative bias of the entire first and second metrology marks relative to each other.

The overlay value is determined based on a difference between the amplitudes, a summation of the amplitudes, and a calibration factor. Even though a calibration factor is required, advantageously, because overlay is determined in this way, overlay value determinations may be relatively insensitive to surrounding structures in the first and second layers of the patterned substrate, for example. The scattering from the surroundings can have any type of period—(device types, other marks, etc.). The mark signal has a specific period corresponding to the grating pitch, illumination settings, and wavelength. Only the scattering at this particular period is filtered in signal processing to determine the amplitude. Therefore, all spatial frequencies of the surroundings that don't match this period, are ignored. The calibration factor is determined based on radiation wavelength, a layer spacing between the first metrology mark and the second metrology mark, a ratio of diffraction efficiencies associated with the first metrology mark in the first layer of the patterned substrate and the second metrology mark in the second layer, grating pitch, grating depth, and/or other information.

In some embodiments, the calibration factor is determined by training a model associated with the overlay metrology system. In some embodiments, the model may comprise an algorithm that is configured to be trained using input output training pairs and/or other training data. The input output training pairs and/or training data may convey radiation wavelengths, layer spacings between the first metrology mark and the second metrology mark, ratios of diffraction efficiencies associated with the first metrology mark in the first layer of the patterned substrate and the second metrology mark in the second layer, grating pitches, grating depths, etc., and corresponding calibration factors. In some embodiments, the algorithm may be configured to learn to predict a calibration factor based on some or all of this information.

In some embodiments, the model and/or the algorithm may comprise one or more individual algorithms. In some embodiments, an algorithm may be a machine learning algorithm. In some embodiments, the machine learning algorithm may be or include a neural network, classification tree, decision tree, support vector machine, or other model that is trained. As an example, neural networks may be based on a large collection of neural units (or artificial neurons). Neural networks may loosely mimic the manner in which a biological brain works (e.g., via large clusters of biological neurons connected by axons). Each neural unit of a neural network may be simulated as being connected with many other neural units of the neural network. Such connections can be enforcing or inhibitory in their effect on the activation state of connected neural units. In some embodiments, each individual neural unit may have a summation function which combines the values of all its inputs together. In some embodiments, each connection (or the neural unit itself) may have a threshold function such that the signal must surpass the threshold before it is allowed to propagate to other neural units. These neural network systems may be self-learning and trained, rather than explicitly programmed, and can perform significantly better in certain areas of problem solving, as compared to traditional computer programs. In some embodiments, neural networks may include multiple layers (e.g., where a signal path traverses from front layers to back layers). In some embodiments, back propagation techniques may be utilized by the neural networks, where forward stimulation is used to reset weights on the “front” neural units. In some embodiments, stimulation and inhibition for neural networks may be more free-flowing, with connections interacting in a more chaotic and complex fashion.

In some embodiments, the one or more processors PRO (FIG. 3, FIG. 13) are configured such that determining the one or more parameters of the fringes comprises determining an amplitude and an average intensity of fringes in the filtered intensity modulated fringe pattern. Advantageously, in these embodiments, determining the overlay value does not require a calibration factor. Instead, the overlay value is determined based on a difference between the amplitude and the average intensity.

In some embodiments, the overlay value is also determined based on a bias of the first and second metrology marks relative to each other. The first amplitude may be associated with a segment of a metrology mark with a positive bias and the second amplitude may be associated with a segment of a metrology mark with a negative bias of the first and second metrology marks relative to each other. In some embodiments, the first amplitude is associated with a positive bias and the second amplitude is associated with a negative bias of the entire first and second metrology marks relative to each other.

The average intensity of fringes may be relatively sensitive to surrounding structures in the first and second layers of the patterned substrate, for example. As a result, first and second metrology marks may comprise a size that is the same as or larger than a C16 (16×16 μm² ) or C20 μDBO mark. This facilitates underfilling a metrology mark with radiation, as described above related to FIG. 5, so that structures on the semiconductor substrate do not alter or interfere with diffracted radiation from the metrology mark. Besides underfilling; one can also use regions of interest (ROIs) in the mark that are further away from the surroundings, while maintaining sufficient ROI-area for signal analysis. (On a large mark, it is easier to ignore from a performance point of view the last 2 μm on the mark edge, than on a smaller mark). If you stay ‘far’ away from the surroundings, you reduce its impact from it (given by the resolution/point spread function of the system).

In some embodiments, determining the one or more parameters of the fringes by determining the amplitude and the average intensity of fringes in the filtered intensity modulated fringe pattern, and determining the difference between the amplitude and the average intensity facilitates determination of the calibration factor. Once the calibration factor has been determined, metrology marks that are smaller than a C16 or C20 μDBO mark can be used for determining the overlay value using the difference between, and summation of, the first and second amplitudes (along with the now determined calibration factor).

In some embodiments, the one or more processors PRO (FIG. 3, FIG. 13) are configured such that determining the one or more parameters of the fringes comprises determining an amplitude and a phase of fringes in the filtered intensity modulated fringe pattern. The overlay value is determined based on the amplitude and the phase. Determining the phase comprises determining a phase difference between: (1) diffracted radiation received from first corresponding top and bottom segments of the first and second metrology mark in the first and second layer of the patterned substrate, and (2) diffracted radiation received from second corresponding top and bottom segments of the first and second metrology mark. In some embodiments, the phase difference comprises information indicative of a reciprocal optical strength of the first and second metrology marks, and overlay is determined at least in part based on the reciprocal optical strength. For example, the first and second corresponding top and bottom segments are spaced from each other by a known distance, and overlay may be determined at least in part based on the phase difference and the known distance.

In some embodiments, the reciprocal optical strength is used by the one or more processors to determine a calibration factor that relates the amplitudes to the overlay value, and determine overlay based on the amplitude and the calibration factor. However, as described herein, in some embodiments, determining the overlay value does not require a calibration factor.

In some embodiments, determining the amplitude comprises determining a first amplitude associated with a segment of a metrology mark with a positive bias, and a second amplitude associated with a segment of a metrology mark with a negative bias, of the first and second metrology marks relative to each other. Determining the phase comprises determining a first phase associated with the segment of the metrology mark with the positive bias, and a second phase associated with the segment of a metrology mark with the negative bias.

In some embodiments, the one or more processors are configured to determine complex amplitudes based on the first and second amplitudes and the first and second phases, determine a real portion of the complex amplitudes, and determine overlay based on the real portion and the positive and negative biases.

In some embodiments, the one or more processors are configured to determine a scaling factor based on the first and second amplitudes, determine a phase factor based on the first and second phases, and determine overlay based on the scaling factor and the phase factor. In some embodiments, determining overlay based on the scaling factor and the phase factor comprises solving a system of two non-linear equations, with one non-linear equation each associated with the scaling factor and the phase factor, and a variable common between the two non-linear equations comprising overlay.

FIG. 7-FIG. 12 provide several examples of various components and/or operations described above.

FIG. 7 illustrates an example overlay (and alignment) metrology system 700. System 700 is the same as or similar to system 10 described above with respect to FIG. 3, with one or more components of system 700 being similar to and/or the same as one or more components of system 10 (and FIG. 7 illustrating additional possible components of the system). In some embodiments, one or more components of system 700 may replace, be used with, and/or otherwise augment one or more components of system 10. In FIG. 7, radiation 702 may be generated and directed to a metrology target (e.g., target 30, a μDBO target in this example) by a radiation source such as source 2 (also shown in FIG. 3)—an incoherent light source in this example.

In this example, metrology target 30 on substrate W comprises gratings in multiple layers of substrate W (though only one layer is shown in FIG. 7 for simplicity). A grating may be formed of solid resist pillars, bars, vias, and/or other features, for example. Metrology target 30 may be sensitive to changes in processing in a patterning process (e.g., optical aberration in the lithographic projection apparatus such as in the projection system, focus change, dose change, etc.) such that process variation manifests in variation in metrology target 30. Accordingly, the measured data from metrology target 30 may be used to determine an overlay value, and/or an adjustment based on the overlay value for one or more manufacturing processes, and/or used as a basis for making the actual adjustment. Again, note that in this example, metrology target 30 may represent multiple layers comprising multiple metrology marks.

FIG. 7 illustrates one or more lenses 704, 706, 708, 710; mirrors 703, 705, and 707; a detection pupil 712; an image plane 714; and an illumination pupil 716 and/or other components configured to direct (and/or are otherwise associated with directing) radiation 702 from source 2 to metrology target 30, and direct diffracted radiation 702 from metrology target 30 toward radiation sensor 4. In this example, sensor 4 comprises a camera, one or more processors, and/or other components. The camera may be configured to generate the metrology signal as described above. The one or more processors may be configured to determine an overlay value based on the metrology signal, also as described above.

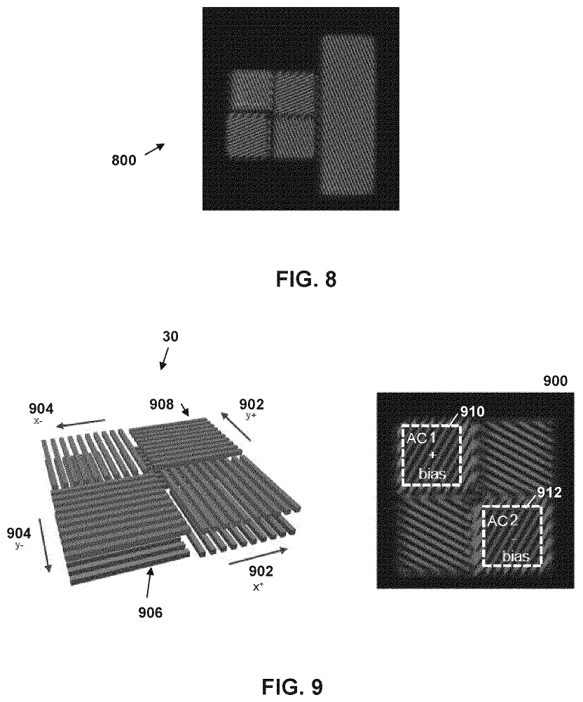

FIG. 8 illustrates an example of a fringe pattern 800, which can be used to determine overlay as described herein. Fringe pattern 800 may be generated based on radiation diffracted by a metrology target (e.g., target 30 shown in other figures). For example, radiation received by a radiation sensor (e.g., sensor 4 shown in FIG. 3 and FIG. 7) comprises diffracted radiation. The radiation sensor (and/or one or more processors PRO of the radiation sensor—see FIG. 3 and FIG. 13) is configured to generate a metrology signal, which comprises an intensity modulated fringe pattern such as fringe pattern 800. The metrology signal also comprises phase information for the radiation received by the radiation sensor. In FIG. 8 and fringe pattern 800, the darker and lighter lines that run at an angle through each rectangle are fringes. Intensity modulation comprises variation in the intensity of radiation reflected by target 30 and received by sensor 4 from across a grating. In FIG. 8, intensity modulation is illustrated by how dark or how light the varying darker and lighter lines are.

The intensity modulated fringe pattern 800 may comprise a one, two, or more dimensional interference pattern. In some embodiments, the radiation sensor is configured such that the intensity modulated fringe pattern 800 for the diffracted radiation comprises an interference pattern generated based on diffracted radiation from the first metrology mark and the second metrology mark of a μDBO target 30 as described above.

The one or more processors PRO (FIG. 3, FIG. 13) are configured such that the intensity modulated fringe pattern 800 is filtered for an expected fringe period. The expected fringe period is determined based on the pitch of the first and/or second metrology marks (e.g., gratings, which have the same pitch, as described above), and/or other information. The one or more processors PRO are configured to determine one or more parameters (e.g., amplitude, phase, and/or other parameters) of fringes (the darker and lighter lines) in the intensity modulated fringe pattern 800 based on the filtered intensity modulated fringe pattern, and/or other information.

FIG. 9 illustrates a first amplitude AC1 and a second amplitude AC2 of fringes 1 and 2 (the darker and lighter lines) in segments or areas 910 and 912 (e.g., gratings), respectively, in a filtered intensity modulated fringe pattern 900. In this example, the first amplitude AC1 is associated with a positive bias 902 (in x and/or y) and the second amplitude AC2 is associated with a negative bias 904 (in x and/or y) of first and second metrology marks 906 and 908 respectively, relative to each other (e.g., which may form a target 30, such as a μDBO target). In some embodiments, as described above, the first amplitude AC1 is associated with a segment or area of a metrology mark 908 with a positive bias 902 (see segment or area 910 marked in fringe pattern 900) and the second amplitude AC2 is associated with a segment or area of a metrology mark 906 with a negative bias 904 (see segment or area 912 (e.g., grating) marked in fringe pattern 900) of the first and second metrology marks 906 and 908 relative to each other. In some embodiments, the first amplitude AC1 is associated with a positive bias 902 and the second amplitude AC2 is associated with a negative bias 904 of the entire first and second metrology marks 906 and 908 relative to each other. The overlay value may be determined based on one or both of these amplitudes, and/or other information.

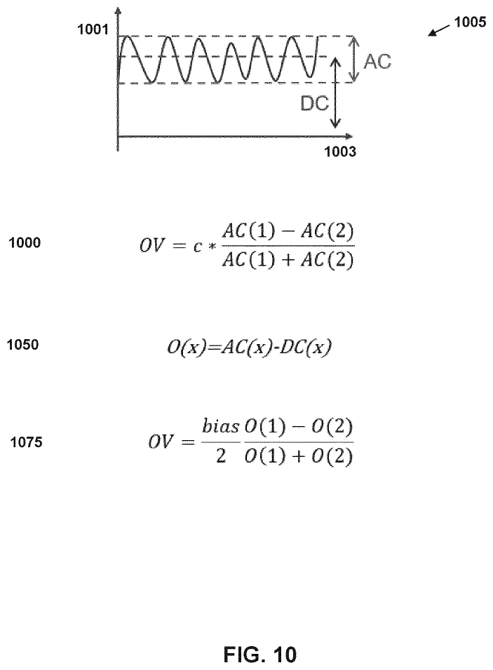

For example, FIG. 10 illustrates determination of overlay OV (e.g., an overlay value) based on amplitude(s) AC from a filtered intensity modulated fringe pattern such as fringe pattern 900 shown in FIG. 9 and/or other information. FIG. 10 illustrates a radiation intensity 1001 versus position 1003 (e.g., across a grating and/or some other portion of a metrology mark) graph 1005 for radiation received by a sensor (e.g., a sensor 4 shown in FIG. 3 and FIG. 3) from a target 30 (FIG. 3, FIG. 7, FIG. 9). Graph 1005 illustrates an example amplitude AC, along with an example average intensity DC of fringes in the filtered intensity modulated fringe pattern.

In some embodiments, as shown in Equation 1000, an overlay value OV is determined based on a difference between amplitudes AC 1 and AC 2, a summation of the amplitudes AC 1 and AC 2, and a calibration factor c. As described above, the calibration factor is determined based on radiation wavelength, a layer spacing between the first metrology mark and the second metrology mark, a ratio of diffraction efficiencies associated with the first metrology mark in the first layer of the patterned substrate and the second metrology mark in the second layer, grating pitch, grating depth, and/or other information. The calibration factor may be determined by training a model associated with the overlay metrology system (e.g., system 700 shown in FIG. 7) and/or using other methods. This model may simulate a sensor to sensor overlay response, for example, and/or other aspects of an overlay metrology system. When overlay is determined in this way, overlay value determinations may be relatively insensitive to surrounding structures in the first and second layers of the patterned substrate, for example. For an asymmetric grating the AC (or AC/DC) component of the fringes changes as a function of asymmetry (maximum for symmetrical marks). A shifted top grating printed on a bottom grating creates in essence an asymmetric grating. Just by monitoring the AC component on a grating without Bias, one cannot tell if the grating moved in the positive or negative direction. By introducing a bias, one can directly tell if the grating moved in the positive or negative direction-the asymmetry (overlay) is directly proportional to the AC change.

In some embodiments, the one or more processors PRO (FIG. 3, FIG. 13) are configured such that determining the one or more parameters of the fringes comprises determining an amplitude AC and an average intensity DC of fringes in the filtered intensity modulated fringe pattern. As described above, in these embodiments, determining the overlay value OV does not require a calibration factor. Instead, the overlay value OV is determined based on a difference between the amplitude AC and the average intensity DC as shown in Equations 1050 and 1075. In Equation 1050, O(x) represents an observable characteristic. Here, the observable characteristic O(x) is the difference between and amplitude AC of fringe(s) x minus the average intensity DC of fringe(s) x. As another example, AC/DC may be used. As shown in Equation 1075, the overlay value OV is also determined based on a bias of the first and second metrology marks relative to each other (see the bias/2 term), a difference between observable characteristics O(1) and O(2) associated with fringe(s) 1 and 2, and a summation of observable characteristics O(1) and O(2) associated with fringe(s) 1 and 2 (e.g., from different segments or areas of a metrology target).

In some embodiments, determining the one or more parameters of the fringes by determining the amplitude and the average intensity of fringes in the filtered intensity modulated fringe pattern, and determining the difference between the amplitude and the average intensity (e.g., first determining OV using equations 1050 and 1075 shown in FIG. 10) facilitates determination of the calibration factor c. Once the calibration factor c has been determined, metrology marks that are smaller than a C16 or C20 μDBO mark can be used for determining the overlay value OV using the difference between, and summation of, the first and second amplitudes (along with the now determined calibration factor) as shown in Equation 1000.

Determining overlay OV according to Equations 1000, 1050, and/or 1075 may lead to wafer real estate savings (e.g., by being able to use smaller marks, and/or a method that is less sensitive to surrounding structures). In addition, measurement accuracy may be improved relative to prior systems because the metrology signal (e.g., gratings from a μDBO overlay target)-which may be used for alignment, overlay, and/or other metrology-can be obtained during one sensing operation.

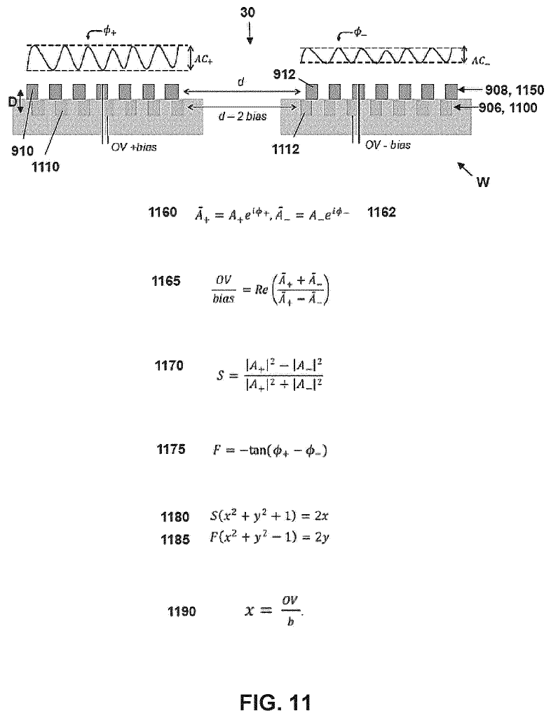

FIG. 11 illustrates determination of overlay OV (e.g., an overlay value) based on amplitude(s) and phase(es) from a fringe pattern such as fringe pattern 900 shown in FIG. 9, according to an embodiment. For example, the amplitude (A or AC, both indications are equivalent) of the fringes includes information about overlay. However, an unknown proportionality constant or calibration factor is needed to map variation in amplitude to overlay (e.g., in nm). This constant or calibration factor depends on stack arrangement, color, target characteristics, and/or other variables. When amplitude is measured, phase is also obtained. Until now, the phase has not been used for overlay determination. The phase of a fringe pattern includes information about the position of a grating or segment of a metrology mark. This is relevant for alignment but was not thought to be relevant for overlay. As described here, phase differences can be used to measure distances between gratings.

The phase difference provides information about the reciprocal optical strength of top and bottom gratings (or segments), which can be used to determine the constant or calibration factor. In this way, the embodiment illustrated in FIG. 11 provides a self-consistent system that does not require a separate calibration step.

In some embodiments, the one or more processors PRO (FIG. 3, FIG. 13) are configured such that determining the one or more parameters of the fringes comprises determining an amplitude (A or AC) and a phase (φ) of fringes in the filtered intensity modulated fringe pattern. The overlay value is determined based on the amplitude and the phase, and/or other information. In this example, a first phase φ₊ and amplitude A₊ are associated with a positive bias (OV +bias, also see 902 in x and/or y in FIG. 9) and a second phase φ_ and amplitude A_ are associated with a negative bias (OV-bias, also see 904 in x and/or y in FIG. 9) of first and second metrology marks 906 and 908 (e.g., which may form a target 30, such as a μDBO target) respectively, relative to each other (e.g., see the distance d between segments or areas 910 and 912 (e.g., gratings), and the d-2 bias distance between segment or area 1110 and 1112 (e.g., gratings)).

Determining the phase comprises determining a phase difference between: (1) diffracted radiation received from first corresponding top segment or area 910 (e.g., grating) and bottom segment or area 1110 (e.g., grating) of the first and second metrology marks (906 and 908 respectively) in first and second layers (1100 and 1150 respectively) of the patterned substrate (W), and (2) diffracted radiation received from second corresponding top segment or area 912 (e.g., grating) and bottom segment or area 1112 (e.g., grating) of the first and second metrology marks (906 and 908). In some embodiments, the phase difference comprises information indicative of a reciprocal optical strength of the first and second metrology marks (906 and 908), and overlay is determined at least in part based on the reciprocal optical strength. For example, the first and second corresponding top (910 and 912) and bottom (1110 and 1112) segments or areas (e.g., gratings) are spaced from each other by a known distance (d), and overlay may be determined at least in part based on the phase difference and the known distance.

In some embodiments, the reciprocal optical strength is used by the one or more processors to determine a calibration factor that relates the amplitudes to the overlay value, and determine overlay based on the amplitude and the calibration factor. However, as described herein, in some embodiments, determining the overlay value does not require a calibration factor.

In some embodiments, determining the amplitude comprises determining a first amplitude associated with a segment of a metrology mark with a positive bias (e.g., A₊ or AC₊), and a second amplitude associated with a segment of a metrology mark with a negative bias (A_ or AC_), of the first and second metrology marks (906 and 908) relative to each other. Determining the phase comprises determining a first phase associated with the segment of the metrology mark with the positive bias (φ₊), and a second phase associated with the segment of a metrology mark with the negative bias (φ_).

In some embodiments, the one or more processors are configured to determine complex amplitudes Ã+and/or Ã_ based on the first and second amplitudes (A₊ and A_) and the first and second phases (φ₊ and φ_, respectively), determine a real portion (Re) of the complex amplitudes, and determine overlay (OV) based on the real portion and the positive and negative biases (bias). For example, complex amplitudes Ã₊ and Ã_ may be determined using Equations 1160 and 1162 shown in FIG. 11. Overlay (OV) may be determined based on the real portion (Re) and the positive and negative biases (bias) using Equation 1165, for example. Bias is a known variable (purposely introduced) in Eq. 1165.

In some embodiments, the one or more processors are configured to determine a scaling factor (S) based on the first and second amplitudes (A₊ and A_, respectively), determine a phase factor (F) based on the first and second phases (φ₊ and φ_, respectively), and determine overlay based on the scaling factor and the phase factor. For example, the scaling factor S may be determined based on Equation 1170 shown in FIG. 11. The phase factor F may be determined based on Equation 1175. In some embodiments, determining overlay based on the scaling factor S and the phase factor F comprises solving a system of two non-linear equations 1180 and 1185, with one non-linear equation each associated with the scaling factor S and the phase factor F, and a variable common between the two non-linear equations comprising overlay. In equations 1180 and 1185, x is related to overlay (OV in prior equations in FIG. 11) as shown in Equation 1190, and y represents a target dependent term that can also be solved for as the second unknown variable in this system of two equations (“b” in equation 1190 is the amount of bias, which is a known variable). Note with regard to FIG. 11 that there are other potential equations that may be used to make these same determinations. In general, these equations are derived from the interference equations of the diffracted light and by finding ways to isolate the overlay (OV) variable from all the other (stack and target) dependent quantities. There may be other ways that allow one to take the OV out of the equations. In general, the equations are non-linear.

The principles described herein are not necessarily limited to use with metrology systems such as system 700 shown in FIG. 7, and further described in FIG. 8-11. These or similar principles may also work in other systems where interference between +1st and −1 st diffracted orders of radiation is observed (and/or where 0th order radiation interferes with the +1st and −1 st diffracted orders and produces fringed images). In addition, these principles are not limited to μDBO, targets, as other DBO like marks may be used. These principles may also enable use of hybrid metrology marks usable for both image-based overlay and diffraction based overlay determinations.

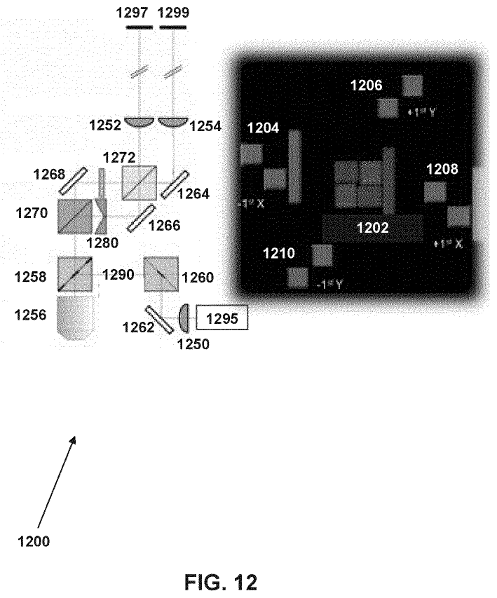

By way of a non-limiting example, FIG. 12 illustrates a metrology system 1200 with a different configuration, along with a fringe pattern 1202 and associated images 1204, 1206, 1208, and 1210 for different diffraction orders. In the example shown in FIG. 12, metrology system 1200 comprises one or more lenses 1250, 1252, and 1254 (e.g., an objective lens); mirrors 1258, 1260, 1262, 1264, 1266, and 1268; beam splitters 1270 and 1272; a wedge 1280; and/or other components configured to direct (and/or are otherwise associated with directing) radiation 1290 from a source 1295 to a metrology target (not shown in FIG. 12), and direct diffracted radiation 1290 from the metrology target toward radiation sensors 1297 and 1299. FIG. 12 illustrates multiple intensity channels, multiple polarization channels, and/or other features. Like system 700 shown in FIG. 7, system 1200 and/or other similar systems may also be used to determine overlay based on amplitudes of filtered intensity modulated fringes as described herein.

Returning to FIG. 6, in some embodiments, operation 610 comprises determining an adjustment for a semiconductor device manufacturing process. In some embodiments, operation 610 includes determining one or more semiconductor device manufacturing process parameters. The one or more semiconductor device manufacturing process parameters may be determined based on one or more detected phase and/or amplitude variations, an alignment value indicated by the metrology signal, an overlay value indicated by the metrology signal, and/or other information. The one or more parameters may include a parameter of the radiation (the radiation used for determining overlay), an overlay inspection location on a layer of a semiconductor device structure, an overlay value, and/or other parameters. In some embodiments, process parameters can be interpreted broadly to include a stage position, a mask design, a metrology target design, a semiconductor device design, an intensity of the radiation (used for exposing resist, etc.), an incident angle of the radiation (used for exposing resist, etc.), a wavelength of the radiation (used for exposing resist, etc.), a pupil size and/or shape, a resist material, and/or other parameters.

A parameter of the radiation used for determining overlay, for example, may include a wavelength, an intensity, an angle of incidence, and/or parameters of the radiation. These parameters may be adjusted to better measure features with specific shapes, enhance the intensity of reflected radiation, increase and/or otherwise enhance (e.g., maximize) the phase and/or amplitude shifts (if any) in reflected radiation from one area of a feature to the next, and/or for other purposes. This may enable and/or enhance detection of more subtle deviations, make the phase and/or amplitude shifts easier to detect, and/or have other advantages.

In some embodiments, operation 610 includes determining a process adjustment based on the one or more determined semiconductor device manufacturing process parameters, adjusting a semiconductor device manufacturing apparatus based on the determined adjustment, and/or other operations. For example, based on a measured overlay value, a lithography exposure may be corrected. As another example, if a determined overlay value is not within process tolerances, the misalignment may be caused by one or more manufacturing processes whose process parameters have drifted and/or otherwise changed so that the process is no longer producing acceptable devices (e.g., overlay measurements may breach a threshold for acceptability). One or more new or adjusted process parameters may be determined based on the overlay determination. The new or adjusted process parameters may be configured to cause a manufacturing process to again produce acceptable devices. For example, a new or adjusted process parameter may cause a previously unacceptable overlay value to be adjusted back into an acceptable range. The new or adjusted process parameters may be compared to existing parameters for a given process. If there is a difference, that difference may be used to determine an adjustment for an apparatus that is used to produce the devices (e.g., parameter “x” should be increased/decreased/changed so that it matches the new or adjusted version of parameter “x” determined as part of operation 610), for example. In some embodiments, operation 604 may include electronically adjusting an apparatus (e.g., based on the determined process parameters). Electronically adjusting an apparatus may include sending an electronic signal, and/or other communications to the apparatus, for example, which causes a change in the apparatus. The electronic adjustment may include changing a setting on the apparatus, for example, and/or other adjustments.

FIG. 13 is a diagram of an example computer system CS that may be used for one or more of the operations described herein. Computer system CS includes a bus BS or other communication mechanism for communicating information, and a processor PRO (or multiple processors) coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a cathode ray tube (CRT) or flat panel or touch panel display for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

In some embodiments, portions of one or more methods may be performed by computer system CS in response to processor PRO executing one or more sequences of one or more instructions contained in main memory MM. Such instructions may be read into main memory MM from another computer-readable medium, such as storage device SD. Execution of the sequences of instructions included in main memory MM causes processor PRO to perform the process steps (operations). One or more processors in a multi-processing arrangement may also be employed to execute the sequences of instructions contained in main memory MM. In some embodiments, hard-wired circuitry may be used in place of or in combination with software instructions. Thus, this description is not limited to any specific combination of hardware circuitry and software.

The term “computer-readable medium” or “machine-readable medium” refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the operations described. Transitory computer-readable media can include a carrier wave or other propagating electromagnetic signal, for example.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) may use electrical, electromagnetic or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN, and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

Various embodiments of the present systems and methods are disclosed in the subsequent list of numbered clauses:
1. An overlay metrology system, comprising: a radiation sensor configured to generate a metrology signal based on diffracted radiation received from a first metrology mark in a first layer of a patterned substrate and a second metrology mark in a second layer of the patterned substrate, the metrology signal comprising an intensity modulated fringe pattern for the diffracted radiation; and one or more processors operatively coupled to the radiation sensor, the one or more processors configured to: filter the intensity modulated fringe pattern for an expected fringe period; determine one or more parameters of fringes in the intensity modulated fringe pattern based on a filtered intensity modulated fringe pattern; and determine an overlay value based on the one or more parameters.
2. The system of clause 1, wherein the second metrology mark is above the first metrology mark.
3. The system of any of the previous clauses, wherein the radiation sensor is configured such that the intensity modulated fringe pattern for the diffracted radiation comprises an interference pattern generated based on diffracted radiation from the first metrology mark and the second metrology mark.
4. The system of any of the previous clauses, wherein the first metrology mark in the first layer is shifted relative to the second metrology mark by a known bias amount.
5. The system of any of the previous clauses, further comprising a radiation source operatively coupled to the one or more processors and the radiation sensor, the radiation source configured to irradiate the first and second metrology marks with radiation.
6. The system of any of the previous clauses, wherein radiation from the radiation source is on axis.
7. The system of any of the previous clauses, wherein radiation from the radiation source is off axis.
8. The system of any of the previous clauses, wherein radiation from the radiation source is spatially incoherent.
9. The system of any of the previous clauses, wherein radiation from the radiation source is spatially coherent.
10. The system of any of the previous clauses, wherein the first and second metrology marks comprise a diffraction-based overlay metrology mark.
11. The system of any of the previous clauses, wherein the first and second metrology marks comprise gratings.
12. The system of any of the previous clauses, wherein the gratings have the same pitch.
13. The system of any of the previous clauses, wherein the expected fringe period is determined based on the pitch.
14. The system of any of the previous clauses, wherein the first and second metrology marks form a Micro Diffraction Based Overlay (μDBO) target, with the first and second metrology marks comprising gratings in the first and second layers of the patterned substrate.
15. The system of any of the previous clauses, the intensity modulated fringe pattern comprises a one or more dimensional interference pattern.
16. The system of any of the previous clauses, wherein the radiation sensor comprises a camera.
17. The system of any of the previous clauses, wherein the one or more processors are configured such that: determining the one or more parameters of the fringes comprises determining a first amplitude and a second amplitude of fringes in the filtered intensity modulated fringe pattern; and determining the overlay value is based on a difference between the amplitudes, a summation of the amplitudes, and a calibration factor.
18. The system of any of the previous clauses, wherein the calibration factor is determined based on radiation wavelength, a layer spacing between the first metrology mark and the second metrology mark, a ratio of diffraction efficiencies associated with the first metrology mark in the first layer of the patterned substrate and the second metrology mark in the second layer, grating pitch, and grating depth.
19. The system of any of the previous clauses, wherein the calibration factor is determined by training a model associated with the overlay metrology system.
20. The system of any of the previous clauses, wherein the first amplitude is associated with a positive bias and the second amplitude is associated with a negative bias of the first and second metrology marks relative to each other.
21. The system of any of the previous clauses, wherein the first amplitude is associated with a segment of a metrology mark with a positive bias and the second amplitude is associated with a segment of a metrology mark with a negative bias of the first and second metrology marks relative to each other.
22. The system of any of the previous clauses, wherein the first amplitude is associated with a positive bias and the second amplitude is associated with a negative bias of the entire first and second metrology marks relative to each other.
23. The system of any of the previous clauses, wherein overlay value determinations are insensitive to surrounding structures in the first and second layers of the patterned substrate.
24. The system of any of the previous clauses, wherein the one or more processors are configured such that: determining the one or more parameters of the fringes comprises determining an amplitude and an average intensity of fringes in the filtered intensity modulated fringe pattern; and determining the overlay value is based on a difference between the amplitude and the average intensity.
25. The system of any of the previous clauses, wherein the overlay value is further determined based on a bias of the first and second metrology marks relative to each other.
26. The system of any of the previous clauses, wherein the first amplitude is associated with a segment of a metrology mark with a positive bias and the second amplitude is associated with a segment of a metrology mark with a negative bias of the first and second metrology marks relative to each other.
27. The system of any of the previous clauses, wherein the first amplitude is associated with a positive bias and the second amplitude is associated with a negative bias of the entire first and second metrology marks relative to each other.
28. The system of any of the previous clauses, wherein the average intensity of fringes is sensitive to surrounding structures in the first and second layers of the patterned substrate.
29. The system of any of the previous clauses, wherein the first and second metrology marks comprise a size that is the same as or larger than a C16 or C20 μDBO mark.
30. The system of any of the previous clauses, wherein determining the overlay value does not require a calibration factor.
31. The system of any of the previous clauses, wherein the system is configured for first performing the operations of any of clauses 24-30, and then performing the operations of any of clauses 17-23.
32. The system of any of the previous clauses, where the operations of any of clauses 24-30 are performed first to determine the calibration factor of any of clauses 17-23, so that metrology marks that are smaller than a C16 or C20 μDBO mark can be used for the operations of any of clauses 17-23.
33. The system of any of the previous clauses, wherein the one or more processors are configured such that: determining the one or more parameters of the fringes comprises determining an amplitude and a phase of fringes in the filtered intensity modulated fringe pattern; and determining the overlay value is based on the amplitude and the phase.
34. The system of any of the previous clauses, wherein determining the phase comprises determining a phase difference between: (1) diffracted radiation received from first corresponding top and bottom segments of the first and second metrology mark in the first and second layer of the patterned substrate, and (2) diffracted radiation received from second corresponding top and bottom segments of the first and second metrology mark.
35. The system of any of the previous clauses, wherein the phase difference comprises information indicative of a reciprocal optical strength of the first and second metrology marks, and overlay is determined at least in part based on the reciprocal optical strength.
36. The system of any of the previous clauses, wherein the first and second corresponding top and bottom segments are spaced from each other by a known distance, and overlay is determined at least in part based on the phase difference and the known distance.
37. The system of any of the previous clauses, wherein the reciprocal optical strength is used by the one or more processors to determine a calibration factor that relates the amplitudes to the overlay value, and determine overlay based on the amplitude and the calibration factor.
38. The system of any of the previous clauses, wherein determining the overlay value does not require a calibration factor.
39. The system of any of the previous clauses, wherein: determining the amplitude comprises determining a first amplitude associated with a segment of a metrology mark with a positive bias, and a second amplitude associated with a segment of a metrology mark with a negative bias, of the first and second metrology marks relative to each other; and determining the phase comprises determining a first phase associated with the segment of the metrology mark with the positive bias, and a second phase associated with the segment of a metrology mark with the negative bias.
40. The system of any of the previous clauses, wherein the one or more processors are further configured to determine complex amplitudes based on the first and second amplitudes and the first and second phases, determine a real portion of the complex amplitudes, and determine overlay based on the real portion and the positive and negative biases.
41. The system of any of the previous clauses, wherein the one or more processors are further configured to determine a scaling factor based on the first and second amplitudes, determine a phase factor based on the first and second phases, and determine overlay based on the scaling factor and the phase factor.
42. The system of any of the previous clauses, wherein determining overlay based on the scaling factor and the phase factor comprises solving a system of two non-linear equations, with one non-linear equation each associated with the scaling factor and the phase factor, and a variable common between the two non-linear equations comprising overlay.
43. The system of any of the previous clauses, wherein the metrology signal is configured to be used by the one or more processors to adjust a semiconductor device manufacturing process.
44. An overlay metrology method, comprising: generating, with a radiation sensor, a metrology signal based on diffracted radiation received from a first metrology mark in a first layer of a patterned substrate and a second metrology mark in a second layer of the patterned substrate, the metrology signal comprising an intensity modulated fringe pattern for the diffracted radiation; filtering, with one or more processors operatively coupled to the radiation sensor, the intensity modulated fringe pattern for an expected fringe period; determining, with the one or more processors, one or more parameters of fringes in the intensity modulated fringe pattern based on a filtered intensity modulated fringe pattern; and determining, with the one or more processors, an overlay value based on the one or more parameters.
45. The method of clause 34, wherein the second metrology mark is above the first metrology mark.
46. The method of any of the previous clauses, wherein the radiation sensor is configured such that the intensity modulated fringe pattern for the diffracted radiation comprises an interference pattern generated based on diffracted radiation from the first metrology mark and the second metrology mark.
47. The method of any of the previous clauses, wherein the first metrology mark in the first layer is shifted relative to the second metrology mark by a known bias amount.
48. The method of any of the previous clauses, further comprising irradiating, with a radiation source operatively coupled to the one or more processors and the radiation sensor, the first and second metrology marks with radiation.
49. The method of any of the previous clauses, wherein radiation from the radiation source is on axis.
50. The method of any of the previous clauses, wherein radiation from the radiation source is off axis.
51. The method of any of the previous clauses, wherein radiation from the radiation source is spatially incoherent.
52. The method of any of the previous clauses, wherein radiation from the radiation source is spatially coherent.
53. The method of any of the previous clauses, wherein the first and second metrology marks comprise a diffraction-based overlay metrology mark.
54. The method of any of the previous clauses, wherein the first and second metrology marks comprise gratings.
55. The method of any of the previous clauses, wherein the gratings have the same pitch.
56. The method of any of the previous clauses, wherein the expected fringe period is determined based on the pitch.
57. The method of any of the previous clauses, wherein the first and second metrology marks form a Micro Diffraction Based Overlay (μDBO) target, with the first and second metrology marks comprising gratings in the first and second layers of the patterned substrate.
58. The method of any of the previous clauses, wherein the intensity modulated fringe pattern comprises a one or more dimensional interference pattern.
59. The method of any of the previous clauses, wherein the radiation sensor comprises a camera.
60. The method of any of the previous clauses, wherein the one or more processors are configured such that: determining the one or more parameters of the fringes comprises determining a first amplitude and a second amplitude of fringes in the filtered intensity modulated fringe pattern; and determining the overlay value is based on a difference between the amplitudes, a summation of the amplitudes, and a calibration factor.
61. The method of any of the previous clauses, wherein the calibration factor is determined based on radiation wavelength, a layer spacing between the first metrology mark and the second metrology mark, a ratio of diffraction efficiencies associated with the first metrology mark in the first layer of the patterned substrate and the second metrology mark in the second layer, grating pitch, and grating depth.
62. The method of any of the previous clauses, wherein the calibration factor is determined by training a model associated with an overlay metrology system.
63. The method of any of the previous clauses, wherein the first amplitude is associated with a positive bias and the second amplitude is associated with a negative bias of the first and second metrology marks relative to each other.
64. The method of any of the previous clauses, wherein the first amplitude is associated with a segment of a metrology mark with a positive bias and the second amplitude is associated with a segment of a metrology mark with a negative bias of the first and second metrology marks relative to each other.
65. The method of any of the previous clauses, wherein the first amplitude is associated with a positive bias and the second amplitude is associated with a negative bias of the entire first and second metrology marks relative to each other.
66. The method of any of the previous clauses, wherein overlay value determinations are insensitive to surrounding structures in the first and second layers of the patterned substrate.
67. The method of any of the previous clauses, wherein the one or more processors are configured such that: determining the one or more parameters of the fringes comprises determining an amplitude and an average intensity of fringes in the filtered intensity modulated fringe pattern; and determining the overlay value is based on a difference between the amplitude and the average intensity.
68. The method of any of the previous clauses, wherein the overlay value is further determined based on a bias of the first and second metrology marks relative to each other.
69. The method of any of the previous clauses, wherein the first amplitude is associated with a segment of a metrology mark with a positive bias and the second amplitude is associated with a segment of a metrology mark with a negative bias of the first and second metrology marks relative to each other.
70. The method of any of the previous clauses, wherein the first amplitude is associated with a positive bias and the second amplitude is associated with a negative bias of the entire first and second metrology marks relative to each other.
71. The method of any of the previous clauses, wherein the average intensity of fringes is sensitive to surrounding structures in the first and second layers of the patterned substrate.
72. The method of any of the previous clauses, wherein the first and second metrology marks comprise a size that is the same as or larger than a C16 or C20 μDBO mark.
73. The method of any of the previous clauses, wherein determining the overlay value does not require a calibration factor.
74. The method of any of the previous clauses, further comprising first performing the method of any of clauses 67-73, and then performing the method of any of clauses 50-56.
75. The method of any of the previous clauses, where the method of any of clauses 67-73 is performed first to determine the calibration factor from any of clauses 60-66, so that metrology marks that are smaller than a C16 or C20 μDBO mark can be used for the method of any of clauses 60-66.
76. The method of any of the previous clauses, wherein the one or more processors are configured such that: determining the one or more parameters of the fringes comprises determining an amplitude and a phase of fringes in the filtered intensity modulated fringe pattern; and determining the overlay value is based on the amplitude and the phase.
77. The method of any of the previous clauses, wherein determining the phase comprises determining a phase difference between: (1) diffracted radiation received from first corresponding top and bottom segments of the first and second metrology mark in the first and second layer of the patterned substrate, and (2) diffracted radiation received from second corresponding top and bottom segments of the first and second metrology mark.
78. The method of any of the previous clauses, wherein the phase difference comprises information indicative of a reciprocal optical strength of the first and second metrology marks, and overlay is determined at least in part based on the reciprocal optical strength.
79. The method of any of the previous clauses, wherein the first and second corresponding top and bottom segments are spaced from each other by a known distance, and overlay is determined at least in part based on the phase difference and the known distance.
80. The method of any of the previous clauses, wherein the reciprocal optical strength is used by the one or more processors to determine a calibration factor that relates the amplitudes to the overlay value, and determine overlay based on the amplitude and the calibration factor.
81. The method of any of the previous clauses, wherein determining the overlay value does not require a calibration factor.
82. The method of any of the previous clauses, wherein: determining the amplitude comprises determining a first amplitude associated with a segment of a metrology mark with a positive bias, and a second amplitude associated with a segment of a metrology mark with a negative bias, of the first and second metrology marks relative to each other; and determining the phase comprises determining a first phase associated with the segment of the metrology mark with the positive bias, and a second phase associated with the segment of a metrology mark with the negative bias.
83. The method of any of the previous clauses, wherein the one or more processors are further configured to determine complex amplitudes based on the first and second amplitudes and the first and second phases, determine a real portion of the complex amplitudes, and determine overlay based on the real portion and the positive and negative biases.
84. The method of any of the previous clauses, wherein the one or more processors are further configured to determine a scaling factor based on the first and second amplitudes, determine a phase factor based on the first and second phases, and determine overlay based on the scaling factor and the phase factor.
85. The method of any of the previous clauses, wherein determining overlay based on the scaling factor and the phase factor comprises solving a system of two non-linear equations, with one non-linear equation each associated with the scaling factor and the phase factor, and a variable common between the two non-linear equations comprising overlay.
86. The method of any of the previous clauses, further comprising using the metrology signal to adjust a semiconductor device manufacturing process.

The concepts disclosed herein may be associated with any generic metrology and/or imaging system for measuring and/or imaging sub wavelength features and may be especially useful with emerging imaging technologies capable of producing increasingly shorter wavelengths.

While the concepts disclosed herein may be used for metrology and/or imaging on a substrate such as a silicon wafer, it shall be understood that the disclosed concepts may be used with any type of metrology and/or imaging systems, e.g., those used for metrology and/or imaging on substrates other than silicon wafers. In addition, the combination and sub-combinations of disclosed elements may comprise separate embodiments.

The descriptions above are intended to be illustrative, not limiting. Thus, it will be apparent to one skilled in the art that modifications may be made as described without departing from the scope of the claims set out below.

1. An overlay metrology system, comprising:
a radiation sensor configured to generate a metrology signal based on diffracted radiation received from a first metrology mark in a first layer of a patterned substrate and a second metrology mark in a second layer of the patterned substrate, the metrology signal comprising an intensity modulated fringe pattern for the diffracted radiation; and
one or more processors operatively coupled to the radiation sensor, the one or more processors configured to:
filter the intensity modulated fringe pattern for an expected fringe period;
determine one or more parameters of fringes in the intensity modulated fringe pattern based on the filtered intensity modulated fringe pattern; and
determine an overlay value based on the one or more parameters.

2. The system of claim 1, wherein the second metrology mark is above the first metrology mark.

3. The system of claim 2, wherein the radiation sensor is configured such that the intensity modulated fringe pattern for the diffracted radiation comprises an interference pattern generated based on diffracted radiation from the first metrology mark and the second metrology mark.

4. The system of claim 2, wherein the first metrology mark in the first layer is shifted relative to the second metrology mark by a known bias amount.

5. The system of claim 1, further comprising a radiation source operatively coupled to the one or more processors and the radiation sensor, the radiation source configured to irradiate the first and second metrology marks with radiation.

6. The system of claim 5, wherein radiation from the radiation source is on axis.

7. The system of claim 5, wherein radiation from the radiation source is off axis.

8. The system of claim 5, wherein radiation from the radiation source is spatially incoherent.

9. The system of any of claim 5, wherein radiation from the radiation source is spatially coherent.

10. The system of any of claim 1, wherein the first and second metrology marks comprise a diffraction-based overlay metrology mark.

11. The system of claim 1, wherein the first and second metrology marks comprise gratings.

12. The system of claim 11, wherein the gratings have the same pitch.

13. The system of claim 12, wherein the expected fringe period is determined based on the pitch.

14. The system of any of claim 1, wherein the first and second metrology marks form a Micro Diffraction Based Overlay (μDBO) target, with the first and second metrology marks comprising gratings in the first and second layers of the patterned substrate.

15. The system of claim 1, wherein the intensity modulated fringe pattern comprises a one or more dimensional interference pattern.

16. An overlay metrology method, comprising:
generating, with a radiation sensor, a metrology signal based on diffracted radiation received from a first metrology mark in a first layer of a patterned substrate and a second metrology mark in a second layer of the patterned substrate, the metrology signal comprising an intensity modulated fringe pattern for the diffracted radiation;
filtering the intensity modulated fringe pattern for an expected fringe period;
determining one or more parameters of fringes in the intensity modulated fringe pattern based on the filtered intensity modulated fringe pattern; and
determining an overlay value based on the one or more parameters.

17. The method of claim 16, wherein the second metrology mark is above the first metrology mark.

18. The method of claim 16, wherein the intensity modulated fringe pattern for the diffracted radiation comprises an interference pattern generated based on diffracted radiation from the first metrology mark and the second metrology mark.

19. The method of claim 16, wherein the first metrology mark in the first layer is shifted relative to the second metrology mark by a known bias amount.

20. The method of claim 16, wherein the first and second metrology marks comprise gratings and wherein the expected fringe period is determined based on a pitch of the gratings.
